(19) United States
(12) Patent Application Publication
(10) Pub. No.: US 2011/0279135 A1
(43) Pub. Date: Nov. 17, 2011

(54) MEMRISTOR ADJUSTMENT USING STORED CHARGE

(76) Inventors: Julien Borghetti, Mountain View, CA (US); Bilberto Medeiros Ribeiro, Menlo Park, CA (US); Dmitri Borisovich Strukov, Mountain View, CA (US)

(21) Appl. No.: 12/781,441

(22) Filed: May 17, 2010

(51) Int. Cl. G01R 27/08

(52) U.S. Cl. 324/705

(57) ABSTRACT

Methods and apparatus pertaining to memory resistors are provided. Electronic circuitry determines energy for changing a non-volatile resistance of a memristor from a present value to a target value. An electric charge corresponding to the energy is stored. An electric pulse is applied to the memristor using the stored charge. The newly adjusted resistance of the memristor is sensed and compared to the target value. Additional electric pulses can be applied in accordance with the comparison. Memristor adjustment by way of feedback control is thus contemplated by the present teachings.

### STATEMENT OF GOVERNMENT INTEREST

This invention has been made with government support. The government has certain rights in the invention.

### BACKGROUND

Memory resistors or “memristors” are electronic constructs that exhibit a non-volatile electrical resistance that is adjustable over a continuous range. The present Ohmic value of a memristor is changed by way of an applied electrical signal. Improved speed, precision and accuracy during memristor adjustment are desirable. The present teachings address the foregoing concerns.

### BRIEF DESCRIPTION OF THE DRAWINGS

The present embodiments will now be described, by way of example, with reference to the accompanying drawings, in which:

FIG. 1 is a block schematic diagram of an apparatus according to one embodiment;

FIG. 2 is a signal diagram depicting an electrical resistance/data value schema according one embodiment;

FIG. 3 is a flow diagram depicting a method according to one embodiment;

FIG. 4 is a schematic diagram depicting electronic circuitry according to one embodiment;

FIG. 5 is a flow diagram depicting a method according to the embodiment of FIG. 4.

### DETAILED DESCRIPTION

### Introduction

Methods and apparatus pertaining to memory resistors (memristors) are provided. Electronic circuitry is used in determining an energy needed to change a non-volatile resistance of a memristor from a present Ohmic value to a target Ohmic value. A certain amount of electric charge corresponding to the energy is stored in a storage capacitor. An electric pulse is applied to the memristor, making use of the stored charge. The newly adjusted resistance of the memristor is then sensed and compared to the target Ohmic value. Additional electric pulses can be applied in accordance with the comparison. Memristor adjustment by way of feedback control is thus contemplated by the present teachings.

In one embodiment, a method includes determining an energy for changing a non-volatile electrical resistance of a memristor from a present value to a target value distinct from the present value. The method also includes storing a certain amount of electric charge corresponding to the energy. Additionally, the method includes applying an electrical pulse to the memristor. The electrical pulse includes the electric charge. The method further includes comparing a sensed value of the non-volatile electrical resistance of the memristor with the target value, the present value redefined by the sensed value.

In another embodiment, an apparatus includes a memristor characterized by a non-volatile electrical resistance. The apparatus also includes electronic circuitry configured to apply electrical pulses to the memristor so as to change the non-volatile electrical resistance. Each of the electrical pulses includes an electric charge stored by the electronic circuitry. The electronic circuitry is further configured to compare a sensed value of, with a target value for, the non-volatile electrical resistance.

### First Illustrative Embodiment

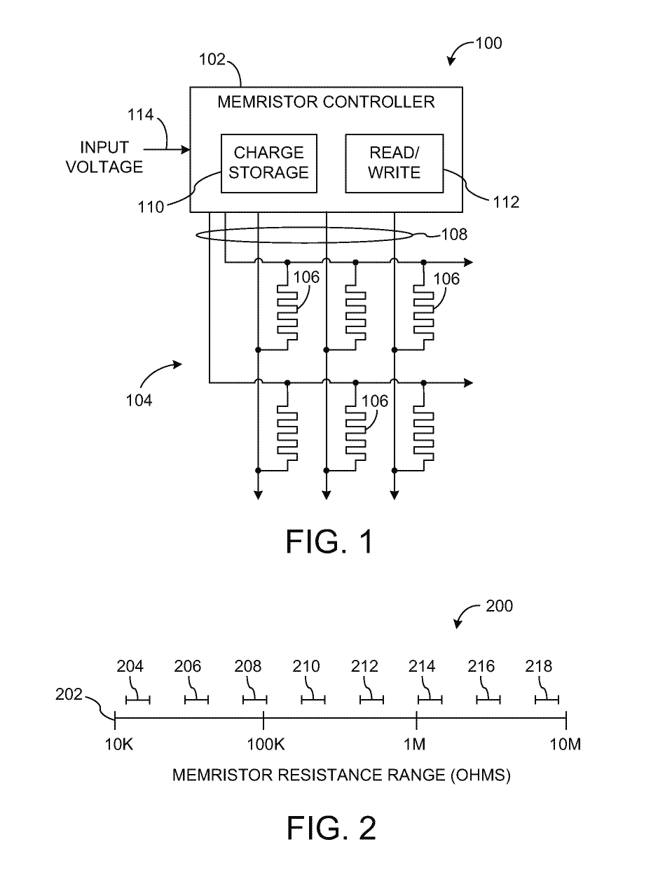

Reference is now directed to FIG. 1, which depicts block schematic diagram of an apparatus 100. The apparatus 100 is illustrative and non-limiting with respect to the present teachings. Thus, other devices, apparatus or systems can be configured and/or operated in accordance with the present teachings.

The apparatus 100 includes a memristor controller (controller) 102. The controller 102 can include or be defined by any suitable electronic circuitry. Non-limiting examples of such controller 102 constituents includes a microprocessor, a microcontroller, an application-specific integrated circuit, (ASIC), analog or digital or hybrid circuitry, a state machine, etc. Other suitable elements and components can also be used. The controller 102 is configured to perform a number of normal control operations with respect to a memory resistor (memristor) array described hereinafter.

The apparatus 100 also includes an array 104 of memory resistors (memristors) 106. A total of six memristors 106 are depicted in the array 104 in the interest of simplicity. However, it is to be understood that other embodiments including any suitable number (thousands, millions, etc.) of memristors 106 can be provided and used according to the present teachings. The memristors 106 are individually accessible—that is, programmable and readable—by the controller 102 by way of respective signal lines (wires or electrical pathways) 108.

Each of the memristors 106 is characterized by an adjustable, non-volatile electrical resistance (i.e., Ohmic value). The particular Ohmic value for a memristor 106 is changed by application of an electrical signal. The controller 102 is configured to apply such electrical signals to respective ones of the memristors 106 by selective use of the signal lines 108. The controller 102 is also configured to controllably vary the magnitude, duration and polarity of the applied electrical signals in accordance with the desired change in electrical resistance of a particular memristor 106. Further elaboration on memristor 106 adjustment according to the present teachings is provided hereinafter.

The controller 102 includes charge storage 110. The charge storage 110 can include one or more capacitors or other energy storage devices. The charge storage 110 can also include other circuitry configured to control the storage and release of electrical energy to and from the storage devices. In one embodiment, the electrical signals applied to the memristors 106 use, at least in part, electrical charges stored by way of the charge storage 110.

The controller 102 also includes read-write resources 112. The resources 112 can include or be defined by any suitable electronic circuitry. The resources 112 are configured to write a plurality of different, predefined data values to the memristors 106 by way applied electrical signals. In one embodiment, the controller 102 is configured to operate in accordance with eight predefined data values (e.g., integers zero through seven, etc.), each represented by a respective Ohmic value or range of values. Other suitable numbers of data values can also be used. Thus, any particular memristor 106 can be used to store any particular predefined data value as a corresponding non-volatile electrical resistance.

The resources 112 are also configured to read the respective data values stored within the respective memristors 106. More specifically, the present (or instantaneous) electrical resistance value of a selected memristor 106 is sensed and that Ohmic value correlated, if possible, with one of the predefined data values. Lookup tables, calibration curves or other suitable memristor 106 information can be used by the controller 102 during the write or read operations.

The controller 102 is coupled to a source of electrical energy at a node 114. The electrical potential (voltage) received at node 114 is typically, but not necessarily, insufficient to successfully change the electrical resistance of a memristor 106 from a present value to a different, target value. Alternatively, it has been determined that memristor 106 electrical resistance can be changed (programmed) more rapidly with increased applied electrical potential. That is, an inverse logarithmic relationship exists between applied programming voltage and programming time.

Therefore, it is desirable to apply electrical pulses to memristors, such pulses may be characterized by voltages greater than that normally used in conventional CMOS or other circuitry. Such electrical pulses, used in changing or programming the memristor electrical resistance values, are derived by way of the charge storage 110.

### First Illustrative Data Schema

Attention is now directed to FIG. 2, which is a signal diagram 200 depicting a resistance/data schema according to one embodiment. The signal diagram 200 is illustrative and non-limiting in nature. Thus, other data values (schema) can also be defined or used in accordance with the present teachings.

The diagram 200 includes an electrical resistance range 202. For purposes of non-limiting illustration, it is assumed that the range 202 depicts a non-volatile electrical resistance range for a memristor 106. The range 202 spans continuously from ten-thousand Ohms to ten-million Ohms in value. The range 202 thus spans three orders of magnitude.

The diagram 200 also includes eight distinct Ohmic sub-ranges 204, 206, 208, 210, 212, 214, 216 and 218, respectively. Each of the sub-ranges 204-218, inclusive, corresponds to value that can be stored by the memristor 106. In one embodiment, the sub-ranges 204-218 correspond to integer values zero, one, two, three, four, five, six and seven, respectively. In another embodiment, the sub-ranges 204-218 correspond to three-bit binary coding values 000, 001, 010, 011, 100, 101, 110 and 111, respectively. In yet another embodiment, the sub-ranges 204-218 correspond to respectively different states “A”, “B”, “C”, “D”, “E”, “F”, “G” and “H”. Other designations or correspondences can also be used.

A total of eight designated Ohmic sub-ranges 204-218 are depicted in the interest of simplicity. However, it is to be understood that the range 202 (or another range according to the present teachings) can be associated with any suitable number of sub-ranges and corresponding data values. Each sub-range 204-218 spans a respective portion of the range 202, rather then being defined by a point. In turn, each sub-range 204-218 span defines a tolerance for the corresponding data value (e.g., one, two, 000, 001, “State A”, “State B”, etc.). Thus, eight respective data values can be stored by way of a memristor 106 with some amount of variation without causing error in the storage or retrieval of such values. Diagram 200 corresponds to an embodiment configured to allow three bits to be encoded in each of the eight distinct Ohmic levels (ranges) 204-218.

### First Illustrative Method

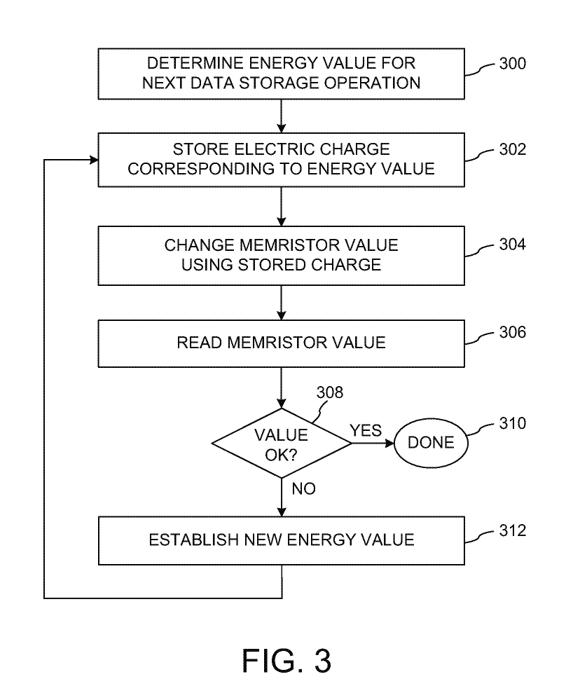

Attention is directed to FIG. 3, which depicts a flow diagram of a method according to one embodiment of the present teachings. The method of FIG. 3 includes particular operations and order of execution. However, other methods including other operations, omitting one or more of the depicted operations, and/or proceeding in other orders of execution can also be used according to the present teachings. Thus, the method of FIG. 3 is illustrative and non-limiting in nature. Reference is also made to FIGS. 1-2 in the interest of understanding the method of FIG. 3.

At 300, an energy value for a next data storage operation is determined. For purposes of non-limiting illustration, it is assumed that the data value of “B” is presently stored within a selected memristor 106. A data value “D” is to replace the data value “B” within the selected memristor 106. The data value “D” corresponds to a resistance sub-range 210 of the selected memristor 106. Thus, the non-volatile electrical resistance of the selected memristor 106 is to be changed from within the sub-range 206 (present value) to within the sub-range 210 (target value). A corresponding energy value is determined or estimated by the memristor controller 102.

At 302, an electric charge corresponding to the energy value is stored. For purposes of the ongoing illustration, it is assumed that a particular electric charge is stored within the charge storage 110. In one embodiment, the charge is stored by applying a particular voltage pulse to a capacitor through a current limiting resistor to precisely control the charging process. Other methods and devices can also be used.

At 304, the memristor electrical resistance value is changed using the stored charge. For purposes of the ongoing example, it is assumed that an electrical pulse is applied to the selected memristor 106 by way of corresponding signal lines 108. The electrical pulse includes the electric charge stored at 302 above. Specifically, a voltage pulse is applied to the selected memristor 106 by series circuit-coupling of the charge storage 110 with the input voltage at node 114. In this way, a voltage pulse having a magnitude greater than the potential at the node 114 is applied to the memristor 106. The non-volatile electrical resistance of the selected memristor 106 is changed to (or at least toward) the sub-range 210.

At 306, the electrical resistance value of the memristor is read. For purposes of the ongoing illustration, the read-write resources 112 of the controllers 102 are used to sense (read) the electrical resistance value of the selected memristor 106. The present value is now redefined as equal to the just-sensed Ohmic value. The present value is correlated, if possible, to one of the predefined data values (“A”, “B”, etc.) for the memristor 106. If the present value does not fall within one of the predefined sub-ranges 204-218, then a particular data value cannot be determined.

At 308, it is determined if the present value of the memristor is OK. For purposes of the ongoing illustration, it is determined if the present Ohmic value is within the sub-range 210. That is, the present value and the target value are compared. If the present value is within the sub-range 210, then the data value storage operation is complete and the method proceeds to step 310 (DONE). However, if the present value is not within the sub-range 210, then the method proceeds to step 312 below.

At 310, the method is done and complete for one operation. The method can dwell at step 310 for any period of time, returning to step 300 above when another data value is to be stored within the selected or another memristor 106.

At 312, a new energy value is determined. For purposes of the ongoing illustration, the new energy value is determined in accordance with comparison made at 308 above. In one embodiment, the energy is calculated in accordance with: E=Q̂2/(2C), where E equals the energy in joules, Q equals the stored charge in Coulombs, and C equals the capacitor value in Farads. This new energy value is directed to changing the electrical resistance of the selected memristor 106 to (or toward) the target value. The method then returns to step 302 above. The steps 302-312 above can be repeated in an iterative, error-elimination manner until the selected memristor 106 is adjusted to within the target Ohmic value.

In general, and without limitation, the present teachings contemplate a number of various methods and circuits for adjusting the non-volatile electrical resistance of a memristor. The characteristic resistance range of a particular memristor can be subdivided into a plurality of distinct sub-ranges. Each sub-range is correlated to a distinct data or state value.

It is noted that a relationship exists between the number of Ohmic sub-ranges defined for a particular memristor and the number of bits that can encoded, or allocated to each sub-range. Specifically: N=2̂B, wherein N equals the number of sub-ranges, and B equals the number of bits assignable to each sub-range. For non-limiting example, if N equals sixteen Ohmic sub-ranges, then B equals four bits assignable to each sub-range (e.g., 0000, 0001, 0010, etc.). Thus, memristor arrays exhibit significant data storage efficiency when compared to conventional, single-bit-per-element technologies.

The memristor adjustment is performed by way of an applied pulse of electrical energy. Each pulse is controllably characterized with respect to magnitude, duration, polarity or other factors. Optionally, each electrical pulse is energized—at least in part—by way of a stored electric charge corresponding to a determined energy for adjusting the memristor to a target Ohmic value. In this way, electrical pulses can be provided that have respective magnitudes exceeding a voltage source coupled to the memristor control circuitry.

The present (or instantaneous) memristor resistance value is measured after the electrical pulse is applied. The present Ohmic value is compared with the target Ohmic value. A new energy value is determined (or estimated) if the present value is not within some margin of error of the target value. The energy determination, electrical charge storage, electrical pulse application and present value sensing can be repeated as needed until the memristor is adjusted to within a predetermined tolerance of the target value.

The present teachings thus contemplate the use of closed-loop, feedback control in association with electrical pulses and electrical charge storage in order adjust the non-volatile electrical resistance of a various memristor devices.

### First Illustrative Circuitry

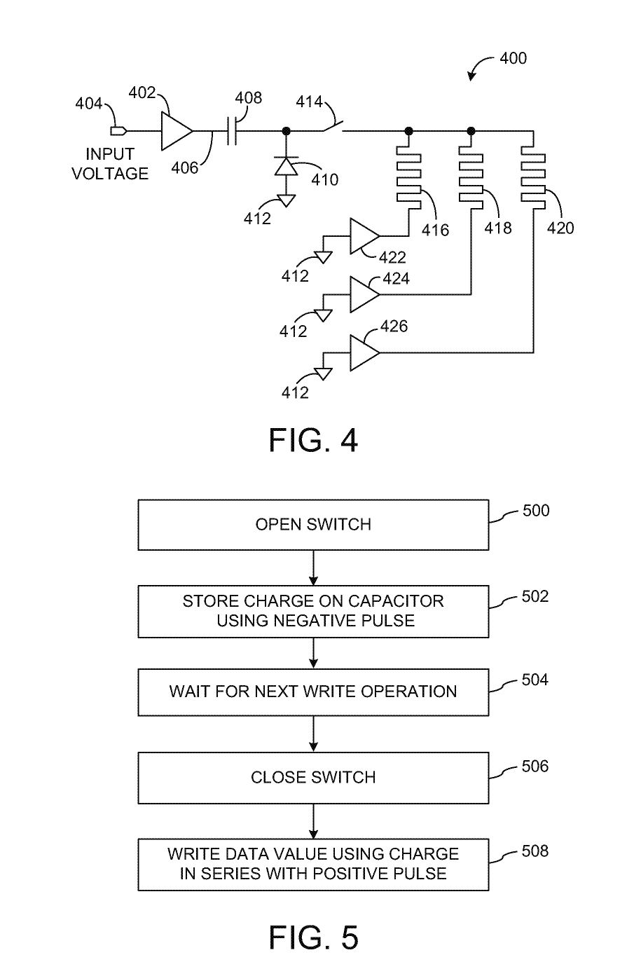

Attention is now directed to FIG. 4, which depicts circuitry 400 in accordance with one embodiment of the present teachings. The circuitry 400 is illustrative and non-limiting with respect to the present teachings. Other circuits, device and electronic apparatus can also be used.

The circuitry 400 includes a buffer or isolation amplifier 402 couple to a source of electrical potential at a node 404. The input voltage at the node 404 is assumed to be, at least some of the time, lesser in magnitude than a value needed to effect a desirable adjustment in a memristor. The buffer 402 is configured to controllably provide this electrical potential at an output node 406.

The circuitry 400 also includes a capacitor 408. The capacitor 408 is coupled to the node 406 and to a diode 410. The diode 410 is in turn coupled to a ground-potential reference plane 412. The capacitor 408 is configured to store an electrical charge provided at the node 406 by way of electrical flow through the diode 410 to ground 412. The buffer 402 is configured to control the magnitude and polarity of an electrical charge stored by way of capacitor 408.

The circuitry 400 also includes a switch 414 and three respective memristors 416, 418 and 420. Each of the memristors 416-420 is electrically coupled to ground potential 412 by way of a respective buffer 422-426. A total of three memristors 416-420 are depicted in the interest of simplicity. However, it is to be understood that the principles of the circuitry 400 can be applied to any suitable number of memristors (thousands, etc.). Normal operation of the circuitry 400 is described below in association with the method of FIG. 5.

### Second Illustrative Method

Attention is directed to FIG. 5, which depicts a flow diagram of a method according to one embodiment of the present teachings. The method of FIG. 5 includes particular operations and order of execution. However, other methods including other operations, omitting one or more of the depicted operations, and/or proceeding in other orders of execution can also be used according to the present teachings. Thus, the method of FIG. 5 is illustrative and non-limiting in nature. Reference is made to FIG. 4 in the interest of understanding the method of FIG. 5.

At 500, a switch coupling a capacitor to one or more memristors is opened. For purposes of a present illustration, it is assumed that the switch 414 is caused to be in an open (electrically non-conductive) state. The switch 414 can be specifically defined by a relay, field-effect transistor, solid-state switch or other suitably controllable device. As such, the capacitor 408 is effectively electrically isolated from the memristors 416-420 by way of the open state of switch 414.

At 502, a charge is stored on the capacitor using a negative-going electrical pulse. For purposes of the present example, it is assumed that the buffer 402 provides an electrical potential at the node 406 that is negative in polarity with respect to ground 412. For purposes of non-limiting illustration, it is assumed that minus five volts is provided as a brief pulse at the node 406. The capacitor 408 stores a corresponding electrical charge, wherein the polarity at node 406 is negative. The magnitude of stored charge (i.e., milli-Coulombs, etc.) corresponds to an energy determination for changing a resistance value of the memristor 418.

At 504, the circuitry waits for the next write operation to be performed. For purposes of the present illustration, the circuitry 400 may be waiting for a period of time in anticipation of storing a data value by way of the memristor 418. The wait period of time can be on the order of nanoseconds, seconds, minutes, etc.

At 506, the switch is closed. For purposes of the present illustration, it is assumed that the switch 414 is caused to be in a closed (electrically conductive) state. As such, the capacitor 408 is electrically coupled to the memristors 416-420.

At 508, a data value is written using the stored charge in series with a positive electrical pulse. For purposes of the present illustration, it is assumed that the buffer 402 provides a brief, plus five volts electrical pulse at the node 406. The voltage at node 406 is in series-adding relationship with the charge stored across the capacitor 408. Contemporaneously, the buffer 424 couples the memristor 418 to the ground potential 412. As such, an electrical pulse is applied to the memristor 418 having a magnitude greater then the source potential provided at the node 404. An electrical pulse of about ten volts peak magnitude is thus applied to the memristor 418 changing the non-volatile electrical resistance thereof. A data value is effectively stored by way of the memristor 418 and can be read, changed, etc., at some future time.

The foregoing method is illustrative of any number of methods contemplated by the present teachings. In general, and without limitation, a buffer or other control elements are used to store an electrical charge across a capacitor. The stored charge is of selectively controllable magnitude and polarity. At a subsequent time, the buffer can couple another electrical pulse in series-adding relationship with the stored charge while the overall electrical pulse is applied to a memristor. Pulses of various magnitudes exceeding a voltage provided by the local power supply or energy source can be derived, resulting in faster and more reliable memristor adjustments and data storage operations.

In general, the foregoing description is intended to be illustrative and not restrictive. Many embodiments and applications other than the examples provided would be apparent to those of ordinary skill in the art upon reading the above description. The scope of the invention should be determined, not with reference to the above description, but should instead be determined with reference to the appended claims, along with the full scope of equivalents to which such claims are entitled. It is anticipated and intended that future developments will occur in the arts discussed herein, and that the disclosed systems and methods will be incorporated into such future embodiments. In sum, it should be understood that the invention is capable of modification and variation and is limited only by the following claims.

What is claimed is:

1. A method, comprising:
determining an energy for changing a non-volatile electrical resistance of a memristor from a present value to a target value distinct from the present value;
storing an electric charge corresponding to the energy;
applying an electrical pulse to the memristor, the electrical pulse including the electric charge; and
comparing a sensed value of the non-volatile electrical resistance of the memristor with the target value, the present value redefined by the sensed value.

2. The method according to claim 1 further comprising applying another electrical pulse to the memristor in accordance with the comparing.

3. The method according to claim 1 further comprising repeating the determining and the storing and the applying and the comparing until the present value is within a tolerance of the target value.

4. The method according to claim 1, the storing the electric charge performed using at least one capacitor.

5. The method according to claim 4, the at least one capacitor being electrically isolated from the memristor by way of a switch during the storing.

6. The method according to claim 4, the at least one capacitor being electrically coupled to the memristor by way of switch during the applying.

7. The method according to claim 1, the target value being one of a plurality of distinct target values, each target value corresponding to a distinct data value storable by way of the memristor.

8. The method according to claim 1 further comprising waiting a period of time between the storing and the applying.

9. The method according to claim 8, the period of time being greater than a sum of times that elapse during the determining and the storing.

10. The method according to claim 1 further comprising operating the memristor at about the target value for a period of time before establishing a different target value.

11. An apparatus, comprising:
a memristor characterized by a non-volatile electrical resistance; and
electronic circuitry configured to apply electrical pulses to the memristor so as to change the non-volatile electrical resistance, each electrical pulse including an electric charge stored by the electronic circuitry, the electronic circuitry further configured to compare a sensed value of with a target value for the non-volatile electrical resistance.

12. The apparatus according to claim 11, the electronic circuitry further configured to apply one or more electrical pulses to the memristor until the sensed value is within a tolerance of the target value.

13. The apparatus according to claim 11, the electronic circuitry further configured to determine a particular energy for changing the non-volatile electrical resistance of the memristor toward the target value before a next electrical pulse is applied to the memristor.

14. The apparatus according to claim 13, the electronic circuitry further configured to store a respective electric charge corresponding to the particular energy before the next electrical pulse is applied to the memristor.

15. The apparatus according to claim 11 further comprising a plurality of memristors arranged as a data storage array, each of the memristors being respectively addressable by the electronic circuitry.

16. The apparatus according to claim 11, the electronic circuitry further configured such that the target value is one of a plurality of different target values storable as data by way of the memristor.

17. The apparatus according to claim 11, the electronic circuitry coupled in feedback control relationship with the memristor.
